(19) United States
(12) Patent Application Publication
(10) Pub. No.: US 2026/0248041 A1
(43) Pub. Date: Aug. 20, 2026

(54) INDEPENDENTLY POWERED BACKPLANE WITH OPTICAL TRANSCEIVERS

(71) Applicant: Applied Materials, Inc., Santa Clara, CA (US)

(72) Inventors: Ameet Bhansali, Pleasanton, CA (US); Nag Patibandla, Santa Clara, CA (US); Shivkumar Chiruvolu, Santa Clara, CA (US)

(21) Appl. No.: 19/219,724

(22) Filed: May 27, 2025

Related U.S. Application Data
(60) Provisional application No. 63/758,966, filed on Feb. 14, 2025.

(51) Int. Cl. H10W 90/00; G02B 6/42; H10D 80/30; H10D 86/80

(52) U.S. Cl. CPC H10W 90/00; G02B 6/4214; G02B 6/428; H10D 80/30; H10D 86/80

(57) ABSTRACT

A device including a first signal pad and a second signal pad. Each signal pad includes an electrically conductive layer coupled to a complementary metal-oxide-semiconductor (CMOS) layer. Each CMOS layer includes a light source driver coupled to a light source and a transimpedance amplifier coupled with a photodetector. The first and second signal pads are connected via an optical medium that is configured to couple a first optical signal between the light source of the first signal pad and the photodetector of the second signal pad and a second optical signal between the light source of the second signal pad and the photodetector of the first signal pad.

### CLAIM OF PRIORTY

The present application claims the benefit under 35 U.S.C. §119(e) of U.S. Provisional Patent Application No. 63/758,966 filed February 14, 2025, which is incorporated by reference herein.

### TECHNICAL FIELD

Embodiments of the present disclosure relate to optical systems, and more particularly to independently powered backplane with optical transceiver.

### BACKGROUND

In a computing system, electrical interconnects can limit the amount of data that can be transferred. For example, electrical interconnects can limit the speed at which data is communicated.

### SUMMARY

In some embodiments, a device includes a first signal pad with a first electrically conductive layer, and a first complementary metal-oxide-semiconductor (CMOS) layer coupled to the first electrically conductive layer, the first CMOS layer comprising a first light source driver coupled to a first light source, and a first photodetector coupled to a first transimpedance amplifier; a second signal pad with a second electrically conductive layer, and a second CMOS layer coupled to the second electrically conductive layer, the second CMOS layer comprising a second light source driver coupled to a second light source, and a second photodetector coupled to a second transimpedance amplifier; and an optical medium that connects the first signal pad with the second signal pad, wherein the optical medium is configured to couple a first optical signal from the first light source with the second photodetector, and wherein the optical medium is configured to couple a second optical signal from the second light source with the first photodetector.

In some embodiments, a device, includes a substrate with an optical medium and a plurality of vias; a signal pad formed on the substrate, the signal pad comprising a complementary metal-oxide-semiconductor (CMOS) backplane that includes a light source driver coupled to a light source and a photodetector coupled to a transimpedance amplifier; and a semiconductor component disposed on the signal pad, wherein a first subset of the plurality of vias are through vias that power the semiconductor component and wherein a second subset of the plurality of vias power the CMOS layer.

A system including: a first semiconductor device; a second semiconductor device; and an embedded photonic interconnect that couples the first semiconductor device to the second semiconductor device, wherein the embedded photonic interconnect includes: a first signal pad coupled to the first semiconductor device, the first signal pad including: a first electrically conductive layer, and a first complementary metal-oxide-semiconductor (CMOS) layer coupled to the first electrically conductive layer, the first CMOS layer including a first light source driver coupled to a first light source, and a first photodetector coupled to a first transimpedance amplifier; a second signal pad coupled to the second semiconductor device, the second signal pad including; a second electrically conductive layer, and a second CMOS layer coupled to the second electrically conductive layer, the second CMOS layer including a second light source driver coupled to a second light source, and a second photodetector coupled to a second transimpedance amplifier; and an optical medium that connects the first signal pad with the second signal pad, wherein the optical medium is configured to couple a first optical signal from the first light source with the second photodetector, and wherein the optical medium is configured to couple a second optical signal from the second light source with the first photodetector.

Numerous other aspects and features are provided in accordance with these and other embodiments of the disclosure. Other features and aspects of embodiments of the disclosure will become more fully apparent from the following detailed description, the claims, and the accompanying drawings.

### BRIEF DESCRIPTION OF THE DRAWINGS

The present disclosure is illustrated by way of example, and not by way of limitation, in the figures of the accompanying drawings in which like references indicate similar elements. It should be noted that different references to “an” or “one” embodiment in this disclosure are not necessarily to the same embodiment, and such references mean at least one.

FIGS. 1A-1C are diagrams of views of example systems including co-packaged optical devices.

FIG. 2A is a top view of an embedded photonic interconnect (EPIC), according to some aspects of the disclosure.

FIG. 2B is a side view of an embedded photonic interconnect (EPIC), according to some aspects of the disclosure.

FIG. 3A illustrates a side-view of a substrate stack for a parallel waveguide link, according to some aspects of the disclosure.

FIG. 3B illustrates a side-view of a substrate stack for a parallel waveguide link, according to some aspects of the disclosure.

FIG. 4A illustrates a side-view of a substrate, according to some aspects of the disclosure.

FIG. 4B illustrates a side-view of a substrate, according to some aspects of the disclosure.

FIG. 4C illustrates a side-view of a substrate, according to some aspects of the disclosure.

FIG. 4D illustrates a side-view of a substrate, according to some aspects of the disclosure.

FIG. 5A illustrates a side-view of a substrate stack, according to some aspects of the disclosure.

FIG. 5B illustrates a side-view of substrate stack, according to some aspects of the disclosure.

FIG. 6 illustrates a side-view of a substrate stack, according to some aspects of the disclosure.

### DETAILED DESCRIPTION

Embodiments of the present disclosure relate to package substrates with independently powered complementary metal oxide semiconductor (CMOS) backplanes that are powered separately from active devices (e.g., processors, memory, etc.) disposed on the CMOS backplanes. Embodiments also relate to independently powered backplane with optical transceiver for package substrates. In embodiments, optical transceivers (e.g., pairs of light sources and photodiodes with associated circuitry for driving the light sources to generate an optical signal based on an electrical signal and for using the photodiodes to generate an electrical signal from an optical signal) are integrated into or connect to the CMOS backplanes and are powered by the CMOS backplanes. Active devices such as memory and processors may have a data connection to the optical transceivers and may be powered separately from the CMOS backplane. Embodiments enable an increase in the amount of memory that can be connected to processors on the package substrate, and therefore increase a bandwidth and capacity of memory that the processors have access to.

In traditional optical interconnects, electrical signals are converted to optical signals and serialized and multiplexed. Because signals are serialized in traditional systems, they are high speed and rely on external modulation of light after an electrical to optical conversion. Also, traditional systems rely on high-speed photodiodes on the receive end as well as systems capable of deserializing high speed signals. Traditional optical interconnects that rely on serialization consume a large amount of power, and have a limited distance between components.

Embodiments also relate to parallel optical interconnects between active components. In embodiments, the parallel optical interconnects are not serialized or multiplexed, in contrast to traditional optical interconnects. Instead, in embodiments each channel may be used with signals that have a single wavelength. In embodiments, the system includes many (e.g., hundreds or thousands) of channels that together form a wide parallel bus. In embodiments, the speed at which individual signals travel may be slowed down as compared to traditional optical interconnects without reducing bandwidth (and even with an increase in bandwidth) as compared to traditional optical interconnects that rely on serialization. Embodiments enable a higher number of components to be optically interconnected (e.g., a processor may be connected to an increased number of memory devices), an increased distance between components that are optically interconnected, and reduced power consumption as compared to traditional optical interconnects in embodiments.

A co-packaged device (e.g., multi-chip module) can include a package substrate having multiple PICs assembled closely together. More specifically, optical components can be integrated on substrates (e.g., silicon (Si) substrate) for fabricating large-scale PICs that co-exist with micro-electronic chips. With the use of an optical transceiver, a received optical signal can be converted to an electrical signal capable of being processed by an integrated circuit, or the processed electrical signal can be converted to an optical signal to be transmitted via an optical fiber.

Instead of ICs (e.g., microchips) that utilize electrons to process information, referred to as electronic ICs (EICs), a PIC utilizes photons (light particles) to process information. A PIC can include multiple photonic components connected on a single chip. Examples of components of a PIC include optical signal generators (e.g., lasers) to generate optical signals (e.g., light), waveguides and/or optical fibers to direct optical signals within the PIC (e.g., similar to wires used to direct electrons), modulators to modulate optical signals to encode information, and detectors to detect and decode the information from the optical signals.

An optical connection between a fiber or fiber array and the PIC optical waveguide, also referred to herein as a connector, can include a connection substrate having multiple grooves formed therein, into which multiple respective optical fibers can be inserted and secured. Each optical fiber can be optically coupled to a respective waveguide. A connection substrate can be formed with a geometry that can provide the proper spacing to achieve optical coupling (e.g., evanescent wave coupling).

One challenge related to optical input/output (I/O) designs targeted for some types of architectures including PICs and optical fibers, such as artificial intelligence (AI) cluster architectures, is the speed and bandwidth of data connections between computing components, such as in a connection between a graphics processing unit (GPUs) and a high-bandwidth memory (HBM) unit. Typically, to reduce latency, improve signal quality, and reduce power consumption, the length of the electrical connection between these computing components may be minimized. In some situations, the speed at which data can be processed may be faster than the data can be reliably delivered. These constraints can limit the design of a semiconductor device, substrate and/or interconnect, increase manufacturing and design costs, and may impact performance of the semiconductor device, substrate, and/or interconnect.

Aspects described herein can address these and other drawbacks by providing substrate with active components and a CMOS backplane that are separately powered. Additionally, aspects described herein can address these and other drawbacks by providing parallel optical interconnects between active components. A substrate may include a silicon core having vias formed therein, and may include a cladding layer with one or more waveguides formed on the silicon core. A CMOS backplane may be formed in or on the cladding layer, and one or more data signal pads may be formed in or on the CMOS backplane. Additionally, one or more optical transceivers may be formed in the CMOS backplane or in a layer formed on or under the CMOS backplane. Each of the signal pads may include an integrated circuit (e.g., an active component such as a memory, processor, etc.) formed thereon. One or more vias may power the integrated circuits through vias in the substrate, and one or more additional vias may separately power the CMOS backplane and/or the optical transceivers.

In an example, a signal pad receives an electrical data signal from an active component such as a processing or memory component (e.g., a GPU). The data signal pad is coupled to an optical transceiver that converts the electrical signal to an optical signal and causes the optical signal to be transmitted via an optical medium to another optical transceiver with is coupled with a respective data signal pad. The optical transceiver coupled with the receiving data signal pad converts the received optical signal into an electrical signal, which can be received and processed by another processing or memory component (e.g., an HBM unit). Each optical transceiver is embedded into the substrate and includes a light-emitter and a light-detector. The optical transceiver can be manufactured such that it occupies a footprint similar to the data signal pad to which the optical transceiver is coupled in embodiments. In some embodiments, the optical medium through which the optical signal is transmitted includes one or more of waveguide(s) and/or optical fibers.

Embodiments described herein can provide for numerous technical advantages, including a reduced latency of interconnects between one or more active components such as processing device, memory devices, or the like, an increased flexibility in interconnect designs, and overall increased performance of components coupled by the interconnect.

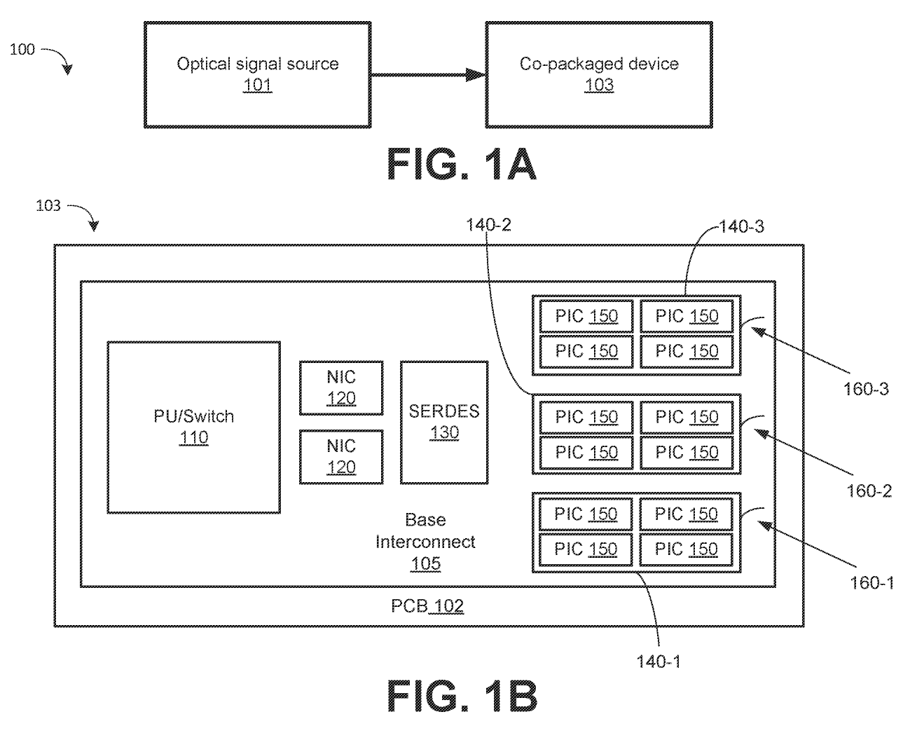

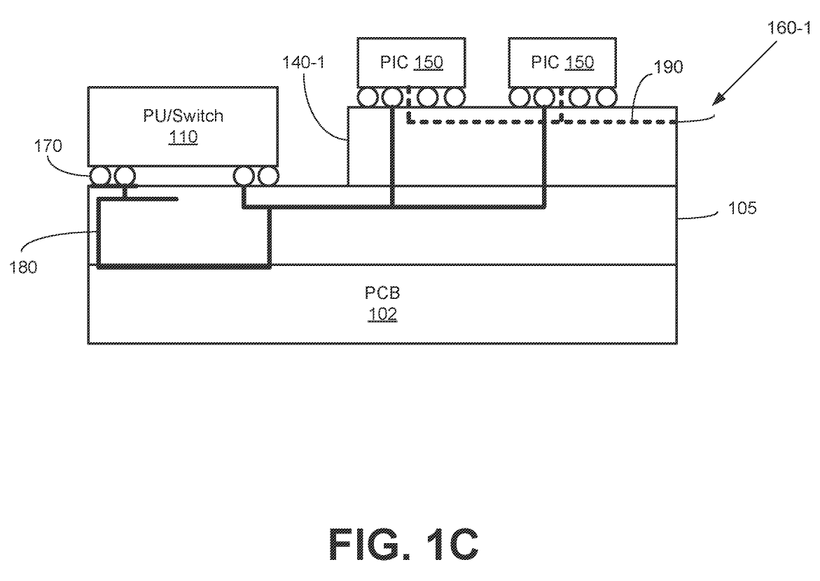

FIG. 1A is a block diagram of system 100 which can transmit data via an optical signal using a serializer-deserializer (SERDES).Such a system 100 can include optical signal source 101 and co-packaged device 103. Optical signal source 101 can provide, as input to co-packaged device, multiple wavelengths of optical signals (e.g., multiple wavelengths of light). For example, optical signal source 101 can include multiple optical signal generators (e.g., lasers) that each generate a respective wavelength of an optical signal. An example of co-packaged device 103 will now be described below with reference to FIGS. 1B-1C.

FIGS. 1B-1C are block diagrams of views of co-packaged device 103. More specifically, FIG. 1B is a top-down view of co-packaged device 103, and FIG. 1C is a side view of co-packaged device 103.

As shown in FIG. 1B, co-packaged device 103 can include printed circuit board (PCB) 102, base interconnect 105, at least one processing unit and/or switch (PU/switch) 110 disposed on base interconnect 105, at least one network interface card (NIC) 120 disposed on base interconnect 105, serializer-deserializer (SERDES) 130 disposed on base interconnect 105, multiple interconnects 140-1 through 140-3 disposed on base interconnect 105, multiple photonic integrated circuits (PICs) 150 disposed on each of interconnects 140-1 through 140-3, and multiple waveguides 160-1 through 160-3 each coupled to a respective one of interconnects 140-1 through 140-3. In some embodiments, and as shown, the number of interconnects is three. However, the number of interconnects should not be considered limiting. In some embodiments, and as shown, each set of PICs includes four PICs150. However, the number of PICs should not be considered limiting.

More specifically, each of interconnects 140-1 through 140-3 can be disposed between respective sets of PICs150 and base interconnect 105. For example, as further shown in FIG. 1C, bumps 170 are disposed between PU/Switch 110 and base interconnect 105, and between PICs 150 and interconnects 140-1 through 140-3. Conductive wires 180 can be formed through the base interconnect 105 and the interconnects 140-1 through 140-3 to enable electrical connections between components of co-packaged device 103 (e.g., PU/switch 110 and PICs150). In some embodiments, embedded photonic interconnects, as described herein below can be formed through the base interconnect 105 and the interconnects 140-1 through 140-3 to enable data transmission via optical connections between components of co-packaged device 103. Additionally, through each of interconnects 140-1 through 140-3, a respective waveguide system can be formed to provide optical signals to the PICs 150. As discussed above, there are multiple disadvantages to SERDES-based systems.

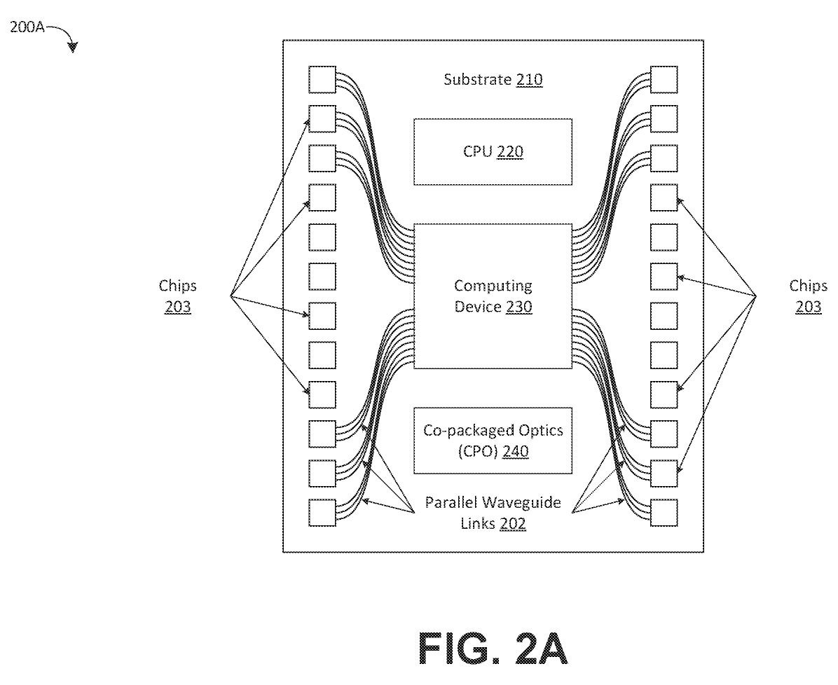

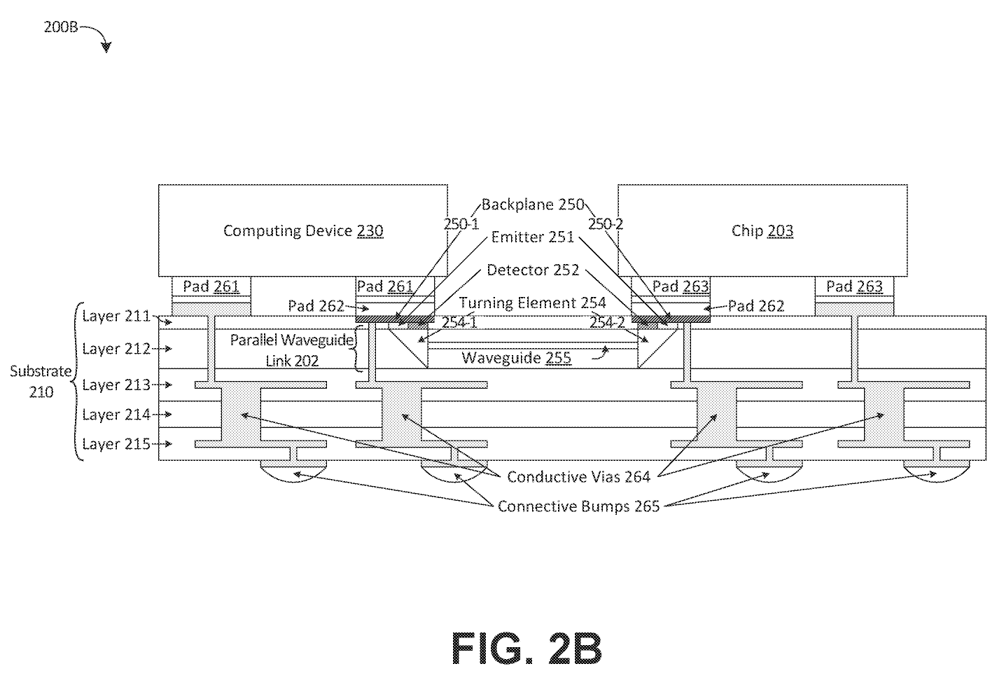

FIG. 2A is a top view of an embedded photonic interconnect (EPIC) 200A, according to some aspects of the disclosure. EPIC 200A includes a central processing unit (CPU) 220, computing device 230, co-packaged optics (CPO) 240, and chips 203 that are bonded to a substrate 210. The computing device 230 is coupled to each of the chips 203 by parallel waveguide links 202.

The CPU 220 can be a processing device for performing various computing tasks, such as generalized tasks. The CPU can communicate with the computing device 230 and the CPO 240 to perform the various computing tasks. The computing device 230 can be connected to each of the chips 203. In some embodiments, the computing device 230 can be one or more of a graphical processing unit (GPU), a data processing unit (DPU), an application specific integrated circuit (ASIC), a CPU, or the like. The CPO 240 can be a photonic integrated circuit (PIC) or the like. In some embodiments, the CPU 220, computing device 230, and CPO 240 can be connected via parallel waveguide links 202. In some embodiments, the EPIC 200A can include other electrical, optical, and/or computing components, which can be bonded to the substrate 210. That is, the inclusion of CPU 220, computing device 230, and CPO 240 here are illustrative, and the parallel waveguide links 202 may be implemented to connect various electrical, optical, computing, and/or memory components that are bonded to a substrate such as the substrate 210.

The chips 203 can be one or more of an electrical, optical, computing, and/or memory component. That is, the chips 203 can be any component that is bonded to a substrate (such as the substrate 210) that is capable of receiving and processing an electrical signal. Examples of components include high performance memory (HPM) stacks, processing devices, and so on.

The computing device 230 can be connected to the chips 203 via parallel waveguide links 202 and/or optical fiber links (not shown). In some embodiments, multiple waveguides (e.g., parallel waveguides) and/or optical fibers can connect each chip 203 to the computing device 230. In contrast to the interconnects described above with reference to FIGS. 1A-C, the parallel waveguide links 202 do not rely on a SERDES to transmit data between the computing device 230 and chips 203. That is, in embodiments data transmitted via the parallel waveguide links 202 may not be packetized or serialized in some embodiments. Parallel waveguide links 202 are further described below with reference to FIG. 2B.

FIG. 2B is a side view of an embedded photonic interconnect (EPIC) 200B, according to some aspects of the disclosure. EPIC 200B includes a computing device 230 and chip 203 bonded to a first substrate layer 211 of the substrate 210 connected by an optical interconnect in a substrate 210. In other embodiments, multiple computing devices may be connected via the optical interconnect, multiple memory devices may be connected via the optical interconnect, and/or one or more computing devices may be connected to one or more memory devices via the optical interconnect. In some embodiments, the substrate 210 includes the first substrate layer 211, a second substrate layer 212, a third substrate layer 213, a fourth substrate layer 214, and/or a fifth substrate layer 215.

The EPIC 200B includes a parallel waveguide link 202. The parallel waveguide link 202 illustratively includes the conductive pads 264 (e.g., signal pads 264-1, 264-2) coupled with respective backplanes 250 (e.g., backplanes 250-1, 250-2 respectively). In some embodiments, the backplanes 250-1, 250-2 include one or more complimentary metal-oxide-semiconductor (CMOS) circuits configured to convert electrical data signals to optical data signals and optical data signals to electrical data signals (e.g., also referred to herein as a “CMOS layer” or “CMOS backplane”). Each backplane 250-1, 250-2 includes or is connected to a respective emitter 251 and detector 252. In some embodiments, the emitter 251 can include a light source such as a laser diode (LD), light emitting diode (LED), micro-light emitting diode (micro-LED), or vertical-cavity surface-emitting laser (VCSEL). In some embodiments, the light source is coupled to a driver circuit. In some embodiments, the detector 252 can include a photodetector. In some embodiments, the detector 252 is coupled to a transimpedance amplifier (not illustrated). Each backplane 250-1, 250-2 is optically coupled with a corresponding turning element 254 (e.g., turning elements 254-1, 254-2, respectively). The turning elements 254-1, 254-2 are optically coupled by the waveguide 255.

The computing device 230 includes conductive pads 261 which are electrically coupled to one or more of conductive pads 262 and/or conductive vias 264 of the substrate 210. In some embodiments, the conductive pads 261 of the computing device 230 are mechanically coupled to the conductive pads 262 or conductive vias 264 of the substrate 210 (e.g., by a soldered connection). In some embodiments, the computing device 230 receives one or more of analog or digital data signals from other components bonded to the substrate 210 through the conductive pad 262. In some embodiments, the computing device 230 receives one or more of power signals, data signals, or the like from other components bonded to the substrate 210 through the conductive vias 264.

The chip 203 includes conductive pads 263 which are electrically coupled to one or more of conductive pads 262 and/or conductive vias 264 of the substrate 210. In some embodiments, the conductive pads 263 of the chip 203 are mechanically coupled to the conductive pads 262 or conductive vias 264 of the substrate 210 (e.g., by a soldered connection). In some embodiments, the chip 203 receives one or more of analog or digital data signals from other components bonded to the substrate 210 through the conductive pad 262. In some embodiments, the chip 203 receives one or more of power signals, data signals, or the like from other components bonded to the substrate 210 through the conductive vias 264.

The conductive pads 262 of the substrate 210 can be electrically and mechanically coupled to a backplane 250. The backplane 250 includes or is connected to and provides power to an emitter 251 and detector 252 for sending and receiving optical communications. The backplane 250 also includes or is connected to internal circuitry to convert electrical signals into optical signals (e.g., as a part of or coupled to the emitter 251), and optical signals into electrical signals (e.g., as a part of or coupled to the detector 252). The backplane 250 can include complementary metal-oxide-semiconductor (CMOS) circuitry to generate the optical signal sent by the emitter 251 and/or to generate an electrical signal from an optical signal received at the detector 252 in embodiments. In some embodiments, the backplane 250 can be electrically coupled to a conductive via 264 to receive one or more of power signals or data signals from one or more components coupled to the substrate 210.

In some embodiments, the second layer 212 of the substrate 210 includes one or more parallel waveguide link(s) 202. The first layer 211 and/or second layer 212 may include or be a cladding layer of the substrate 210 in embodiments. A parallel waveguide link 202 can refer to a group of electro-optical components that enable transmission of data signals between two active components (e.g., between the computing device 230 and the chip 203). Illustratively, the parallel waveguide link 202 in FIG. 2B includes the backplane 250-1 (coupled to the computing device 230), the backplane 250-2 (each including respective emitters 251 and detectors 252), the turning element 254-1 (optically coupled with the backplane 250-1), the turning element 254-2 (optically coupled with the backplane 250-2) and the waveguide 255 optically coupled between the turning element 254-1 and the turning element 254-2.

In some embodiments, during operation of the EPIC 200B, the computing device 230 can send a data signal to the chip 203 via the parallel waveguide link 202. The data signal can be an electrical data signal that is received at the backplane 250-1, where the electrical data signal is converted to an optical data signal. The emitter 251 of the backplane 250-1 transmits the optical data signal via the waveguide 255. The optical data signal is received by the detector 252 of the backplane 250-2. The backplane 250-2 converts the received optical data signal to an electrical data signal that can be processed by the chip 203. The chip 203 can similarly send a data signal to the computing device 230 via the parallel waveguide link 202, and the computing device 230 can similarly receive the data signal from the chip 203. As described above, and in some embodiments, the transmitted optical data signals may not be packetized, serialized or multiplexed. In some embodiments, the transmitted optical data signals may be transmitted in real time or near real time without use of a scheduling component such as a SERDES, or the like. In some embodiments, optical data signals transmitted via the parallel waveguide links 202 in the EPIC 200B can have the same wavelength. That is, the optical data signal of a first waveguide link can have the same wavelength as the optical data signal of a second waveguide link in the parallel waveguide links 202 in some embodiments. In some embodiments, waveguide links of the parallel waveguide links 202 can have distinct wavelengths. In some embodiments, the EPIC 200B may include hundreds, thousands, or more of parallel waveguide links 202.

Parallelized data transfer via the parallel waveguide links 202 has the benefit of lowering data transmission latency and power consumption. Since a SERDES or similar packetizing component or data transmission scheduler is not used in embodiments, energy is not used to power the SERDES or lost in converting parallel communications into a serial communication that may be multiplexed across one or a few optical connections. It should be noted that while the introduction and use of a massive amount of parallel waveguides 202 (e.g., thousands or more) can allow all waveguides to transmit a single optical signal, and thus operate with a single wavelength, in some embodiments, these parallel waveguide links 202 may also be configured to transmit multiplexed optical signals.

In some embodiments, the emitter 251 can include one or more of a light source, a driver circuit, a modulator, optical coupling elements, and/or thermal management elements.

In some embodiments, the light source can include a laser diode (LD) or a light-emitting diode (LED). In some embodiments, the driver circuit can drive the light source. In the illustrative example, the driver circuit can provide power to the light source from components coupled to the substrate 210, as illustrated by the connection between the backplanes 250 and respective conductive vias 264.

In some embodiments, the modulator is configured to encode information onto the light source to generate the optical signal. In some embodiments, the modulator and the light source can be the same element (e.g., direct modulation). In some embodiments, the modulator can be external to the light source and can include one or more of an electro-optic modulator or acousto-optic modulator. In some embodiments, modulation schemes can include one or more of amplitude modulation, phase modulation, frequency modulation, or the like.

In some embodiments, the optical coupling elements can include optical transmission media, such as optical fibers or free-space, and one or more coupling elements such as lenses, mirrors, fiber couplers, or the like.

In some embodiments, the thermal management elements can be configured to maintain the stability of the optical emitter and/or optical detector. In some embodiments, the thermal management elements can include one or more of heat sinks, thermoelectric coolers (TECs), temperature sensors, or the like. In some embodiments, thermal management elements can be used to control which wavelengths are transmitted by the respective emitter.

The EPIC 200B can include connective bumps 265 (e.g., micro bumps) that are electrically and mechanically coupled to conductive vias 264. The connective bumps 265 can be configured to mechanically bond the EPIC 200B to a computing element and/or power source and allow for transmission of electrical signals and/or power from the affixed computing element and/or power source up to the components of the EPIC 200B through the conductive vias 264. In some embodiments, connective bumps 265 are not electrically coupled to a respective conductive via, but instead are used primarily for mechanical coupling.

The layers of the substrate 210 in the EPIC 200B are illustrative, and may include one or more of ground planes, signal planes, power planes, insulator planes, or the like. In some embodiments, the substrate 210 can include more or less substrate layers.

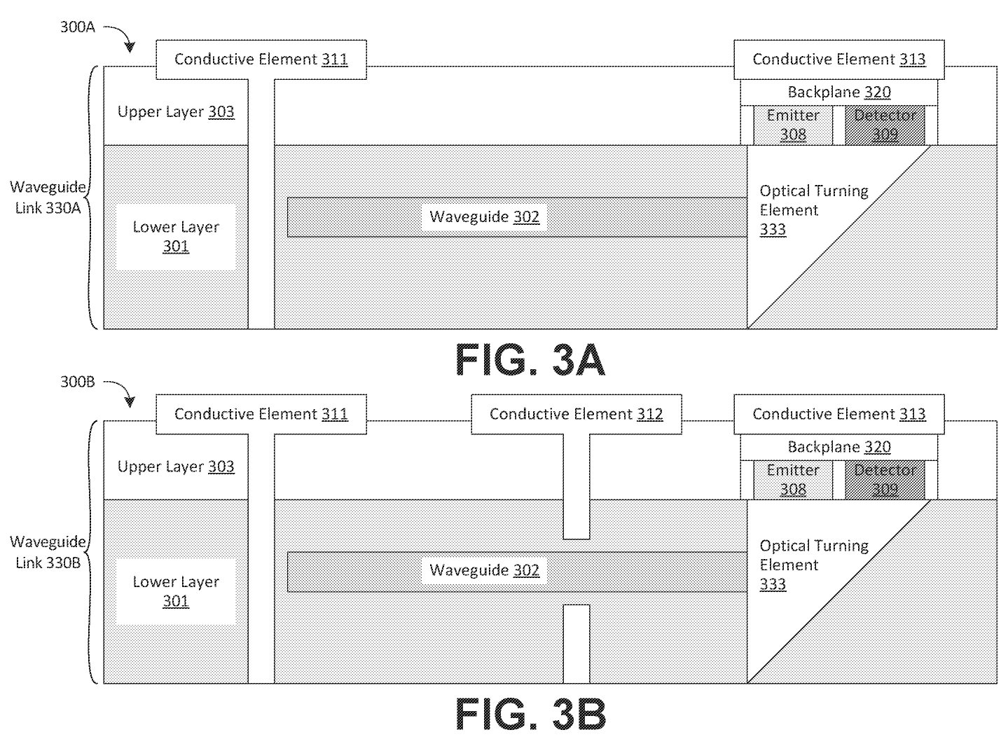

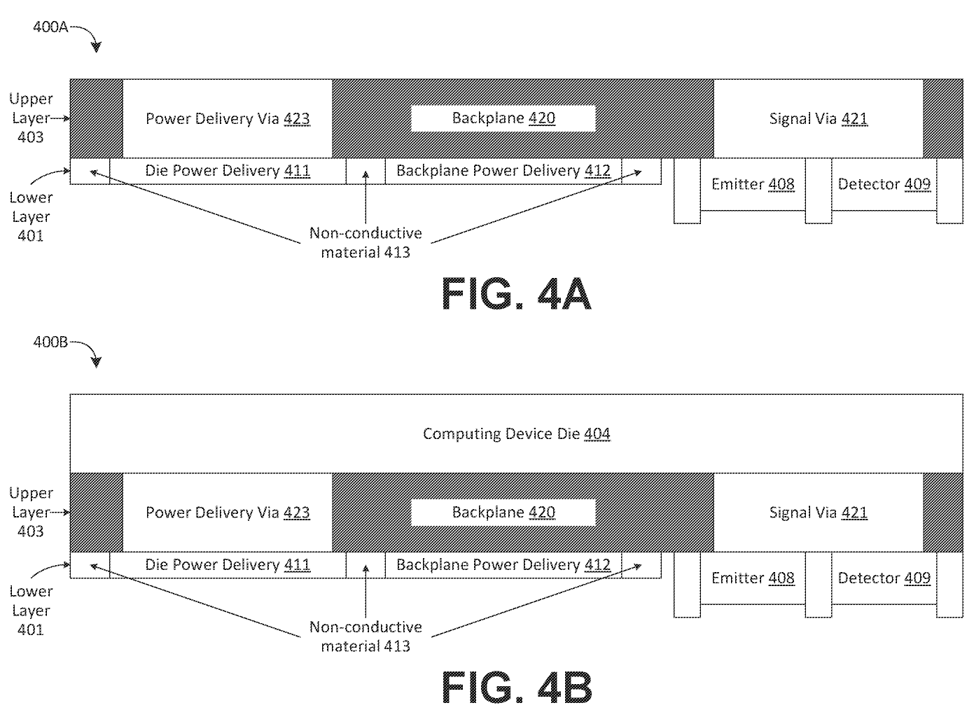

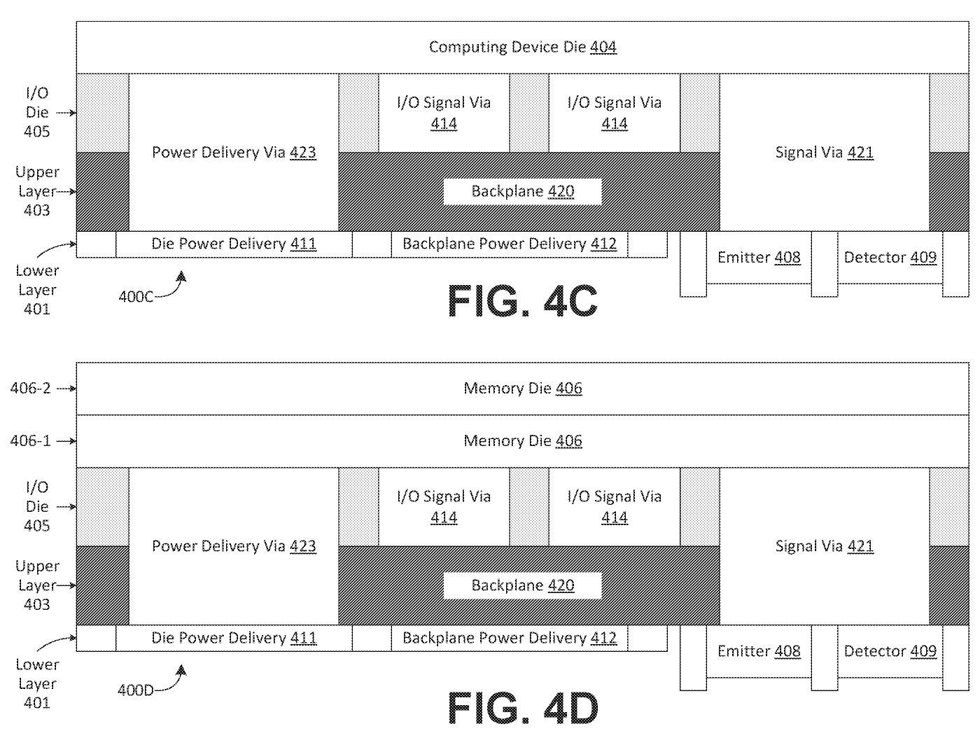

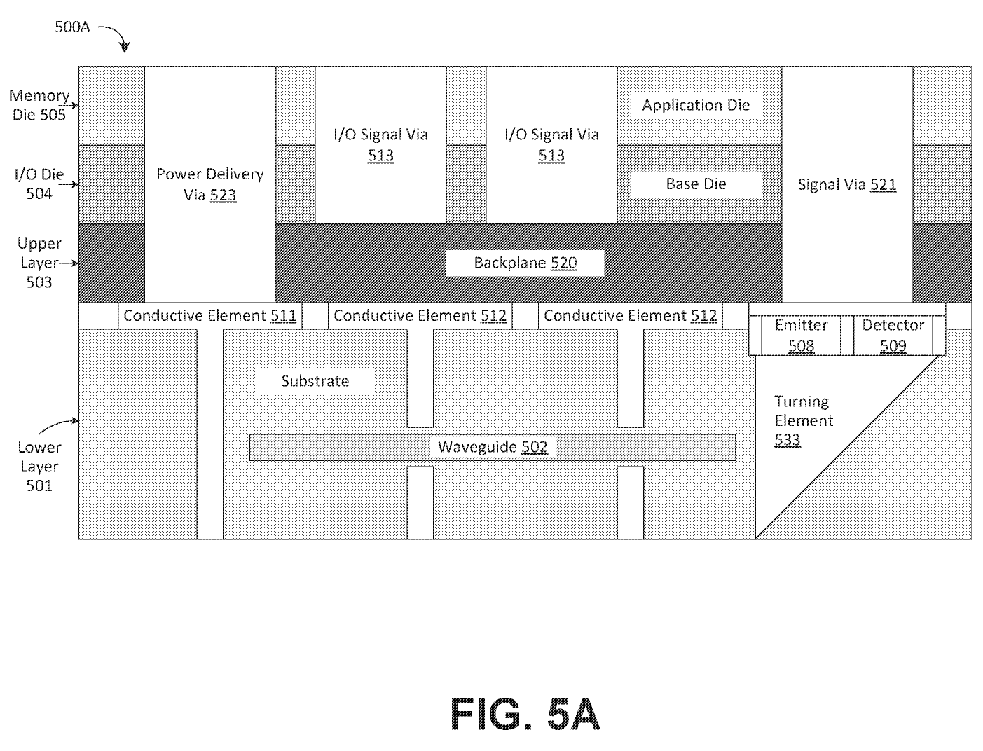

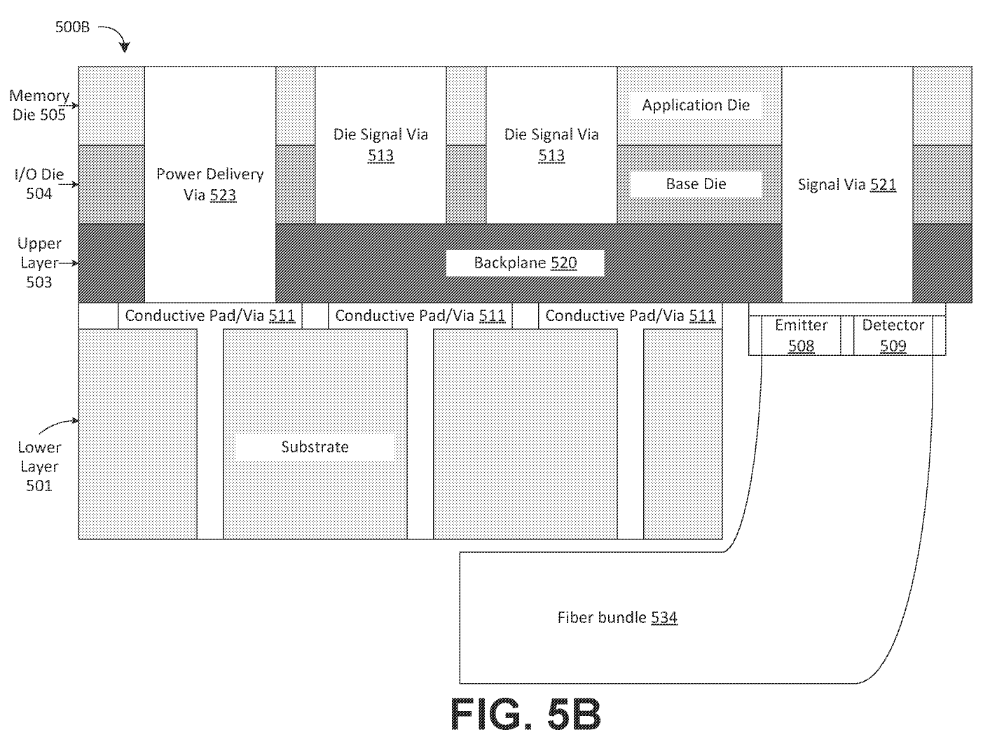

FIG. 3A illustrates a side-view of a substrate stack 300A for a parallel waveguide link 330A, according to some aspects of the disclosure. The substrate stack 300A includes lower layer 301 and upper layer 303. The upper layer 303 includes a portion of a conductive element 311, a portion of conductive element 313, and backplane 320. The lower layer 301 includes a portion of conductive element 311, waveguide 302, and optical turning element 333. In some embodiments, the lower layer 301 includes a portion of backplane 320 (not illustrated). In some embodiments, the upper layer 303 can include or be bonded to additional substrate layers (as further described below with reference to FIGS. 4A-5B). In some embodiments, the upper layer 303 can include or be a part of a semiconductor die or semiconductor device, such as a memory die or memory component, a processor die or processing component, an input/output (I/O) die, or the like.

In some embodiments, the conductive element 311 includes a conductive pad coupled to a conductive via such as a through-silicon via (TSV) as illustrated (also referred to herein plurally as through-silicon vias (TSVs)). In alternative embodiments, the conductive element 311 can be either a conductive pad or a conductive via. In some embodiments, the conductive element 311 includes a portion (e.g., the top pad) that mechanically and electrically couples with a computing device or chip (e.g., a CPU, GPU, DPU, memory device, chip, or the like). The conductive element 311 can include an electrically conductive layer that is designed to electrically conduct one or more of power signals and/or data signals to another electrically conductive element (not illustrated). In some embodiments, the conductive element 311 can include power delivery pads. That is, electrically conductive pads that receive power signals for one or more elements of the waveguide link 330A. In some embodiments, a portion of the conductive element is embedded in a cladding layer. That is, in some embodiments, the upper layer 303 can be, or can include, a cladding layer. In alternative embodiments, the cladding layer can sit on top of the upper layer 303 (not illustrated).

In some embodiments, the conductive element 313 is electrically coupled with the backplane 320. The backplane 320 can be the same as or similar to the backplane 250 described above with reference to FIG. 2B. The backplane includes or is coupled to the emitter 308 and detector 309 and circuitry needed to convert electrical signals into optical signals, and optical signals into electrical signals, as similarly described above with reference to FIG. 2B. For example and in some embodiments, a light source driver circuit can be coupled with the emitter 308 to drive the light source of the emitter 308. In another example and in some embodiments, a transimpedance amplifier circuit can be coupled with the detector 309

In some embodiments, a portion of the conductive element 311, a portion of the conductive element 313, and the backplane 320 can be included in an upper layer 303. In some embodiments, a portion of the conductive element 311, the waveguide 302, and the optical turning element 333 can be included in a lower layer 301. In some embodiments, the optical turning element 333 can include one or more of a mirror, a prism, a polished end of an optical fiber, a grating or diffractive element, a waveguide, or the like. In some embodiments, the optical turning element can be configured to redirect an optical signal received from the waveguide 302 to the backplane 320 (e.g., the detector 309 of the backplane 320). In some embodiments, the optical turning element 333 can be configured to redirect an optical signal received from the backplane 320 (e.g., from the emitter 308) to the waveguide 302.

FIG. 3B illustrates a side-view of a substrate stack 300B for a parallel waveguide link 330B, according to some aspects of the disclosure. FIG. 3B illustrates that a substrate stack 300B can be the same as or similar to the substrate stack 300A of FIG. 3A, albeit with additional conductive elements 312 which are intersected by the waveguide 302. That is, in some embodiments, the conductive element 311 may wrap around the waveguide (e.g., dimensionally out of the page as illustrated). In alternative embodiments, the waveguide 302 is sitting in front of the conductive element 311, which is shown as “broken” in this cross-sectional depiction only for clarity of illustration. As described above with reference to FIGS. 2A-B, the conductive elements 311 can be configured to transmit electrical signals from components coupled to the parallel waveguide link 300A (not illustrated) to a CPU, GPU, DPU, memory device, or the like coupled to the conductive elements 311 and conductive elements 312.

FIG. 4A illustrates a side-view of a substrate 400A, according to some aspects of the disclosure. The substrate 400A includes a lower substrate layer 401 and an upper substrate layer 403. In some embodiments, the lower substrate layer 401 includes conductive pads for power and/or data signal delivery to components of the substrate 400A (e.g., die power delivery 411, backplane power delivery 412, etc.). The conductive pads of the lower layer 401 can be separated by non-conductive material 413, as illustrated. In some embodiments, the lower layer 401 includes a portion of the emitter 408 and detector 409, and/or other elements used to transmit and receive optical signals, as well as convert data signals between electrical data signals and optical data signals.

The elements of the lower layer 401 can be electrically and/or mechanically coupled to elements of the upper substrate layer 403. In some embodiments, the upper substrate layer 403 includes a power delivery via 423, and a backplane 420. The backplane 420 can a signal via 421, which is coupled to the emitter 408 and detector 409. The signal via 421 is configured to connect the backplane 420 to a computing device coupled to the backplane 420 (e.g., as illustrated below in FIG. 4B). In some embodiments, the power delivery via 423 does not electrically connect to the backplane 420, but rather is configured to electrically couple with a computing device coupled to the backplane 420 (as illustrated below in FIG. 4B). In such embodiments, the backplane 420 receives power via the backplane power delivery 412, as illustrated.

FIG. 4B illustrates a side-view of a substrate 400B, according to some aspects of the disclosure. The substrate 400B can include a lower substrate layer 401, an upper substrate layer 403, and a computing die 404. In some embodiments, the elements of the lower layer 401 and the elements of the upper layer 403 can be the same as or similar to the corresponding elements described above with reference to FIG. 4A.

In some embodiments, the power delivery via 423 can provide power to the computing device 403 via a conductive pad in the lower layer 401 (e.g., the die power delivery 411). In some embodiments, the power delivery via 423 does not provide a power signal to the backplane 420, which is instead powered via a separate conductive pad (e.g., the backplane power delivery 412). The computing device die 404 receives data signals from components coupled to the substrate 400B (not illustrated) via the signal via 421. The signal via 421 is coupled to the emitter 408 and detector 409 of the backplane 420 which are configured to optically couple with an optical transmission medium such as an optical fiber, waveguide, or the like and enable optical transmission of electrical signals from- and to- the signal via 421, as described herein.

FIG. 4C illustrates a side-view of a substrate 400C, according to some aspects of the disclosure. The substrate 400C can include a lower substrate layer 401, an upper substrate layer 403, an input/output (I/O) die 404, and a computing die 404. In some embodiments, the elements of the lower layer 401, the elements of the upper layer 403, and the computing die 404 can be the same as or similar to the corresponding elements described above with reference to FIGS. 4A-B.

In some embodiments, the I/O die 405 can include one or more I/O signal vias 414. The I/O signal vias 414 can connect the I/O die 405 to the computing device die 404. In some embodiments, the I/O die 405 can facilitate communication between the computing device die 404 and other components bonded to the substrate 400C. In some embodiments, the I/O die 405 can facilitate communication between the computing device die 404 and other layers of the substrate 400C (e.g., as illustrated in FIG. 4D). In some embodiments, the I/O die 405 can facilitate communication all external communications to- or from- the computing device die 404.

As illustrated, the I/O die 405 can be positioned between the physical connection layer (e.g., the lower layer 401) and the computing device die 404. In some embodiments, the I/O die 405 can translate data signals that are internal to the computing device die 404 into data signals that can be transmitted and/or interpreted by other components bonded to the substrate 400C. In some embodiments, this translation can include transmitting the data signals of the computing device die 404 with certain protocols, level-shifting the data signals of the computing device die 404, or the like. For example, the I/O die 405 can manage communication protocols for the computing device die 404 such as peripheral component interconnect express (PCIe), universal serial bus (USB), memory interfaces (e.g., double data rate (DDR) random access memory (RAM), or high bandwidth memory (HBM)), or the like.

In some embodiments, the I/O die 405 can include one or more signal buffers that are configured to improve or maintain signal integrity of data signals that are transmitted to or from the computing device die 404. In some embodiments, the I/O die 405 can perform hardware-based transmitter and receiver checks on data signals that are sent and received. In some embodiments, such as in high-speed communications, the I/O die 405 can be configured to mitigate signal integrity issues such as crosstalk, noise, and/or attenuation.

In some embodiments, the I/O die 405 can be an application-specific die, such as an HBM die. In such embodiments, the I/O die 405 can have certain optimizations that improve the functionality of the I/O die 405 for a specific purpose (e.g., an HBM device). For example, the I/O die 405 used in an HBM application can be configured to prioritize memory access and management (particularly of dynamic random-access memory (DRAM)). Further, the I/O die 405 used in an HBM application may prioritize high-speed communications of a particular protocol as opposed to widely supporting multiple communication protocols.

FIG. 4D illustrates a side-view of a substrate 400D, according to some aspects of the disclosure. The substrate 400D can include a lower substrate layer 401, an upper substrate layer 403, an input/output (I/O) die 404, and one or more memory die 406. In some embodiments, the elements of the lower layer 401, the elements of the upper layer 403, and the I/O die 405 can be the same as or similar to the corresponding elements described above with reference to FIGS. 4A-C.

In some embodiments, the memory die 406 can be one of multiple memory dies 405-1, 405-2. In some embodiments, the memory dies 405-1, 405-2 can be included in a stack of memory dies that make up a memory device, such as a DRAM memory device. In some embodiments, the stack of memory dies that includes memory dies 405-1, 405-2 can be used in as an HBM memory device. In some embodiments, the stack of memory dies that includes memory dies 405-1, 405-2 can be used as a non-volatile storage array.

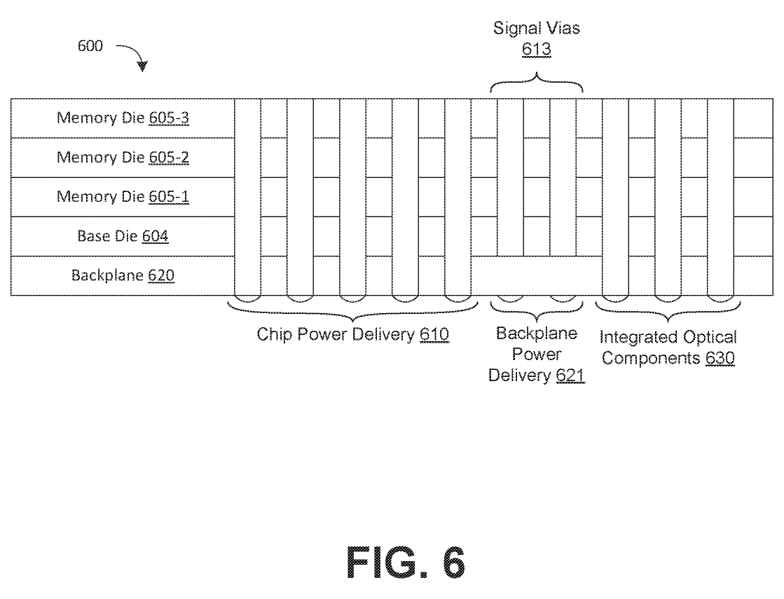

In some embodiments that include stacks of memory dies 405-1, 405-2, multiple TSVs can run down through the stacks of memory dies (as illustrated and described with reference to FIG. 6, below). In some embodiments, the I/O die 405 in the substrate 400D can be an application-specific I/O die (e.g., an HBM base die).

FIG. 5A illustrates a side-view of a substrate stack 500A, according to some aspects of the disclosure. The substrate stack 500A can include a lower layer 501, an upper layer 503, an I/O die 504, and one or more memory dies 505. The substrate stack 500A may be formed on a substrate, such as a silicon core substrate in some embodiments.

The lower layer 501 can include a lower layer 501, upper layer 503, I/O die 504, and memory die 505. In some embodiments, the I/O die 504 is a base die for a specific implementation or application (e.g., an I/O die specific for a memory interface). In some embodiments, the memory die 505 is an application die (e.g., a die with a specific application or purpose, such as a memory die, a computing device die, or the like).

The lower layer 501 can include a waveguide 502, a portion of conductive element(s) 511, 512, and turning element 533. In some embodiments, the lower layer 501 can include a portion of an emitter 508 and/or a detector 509. In some embodiments, the waveguide 502, conductive element(s) 511, 512, turning element 533, emitter 508, and detector 509 can be the same as or similar to respective corresponding elements described above with reference to FIGS. 3A-B, and 4A-D.

The upper layer 503 can include the backplane 520, a portion of conductive elements 511, 512, a portion of power delivery via 523 and a portion of signal via 521. In some embodiments, the upper layer 503 includes a portion of the emitter 508 and/or a portion of the detector 509. In some embodiments, the backplane 520, power delivery via 523 and signal via 521 can be the same as or similar to corresponding elements described above with reference to FIGS. 3A-B, and 4A-D.

The I/O die 504 can include a portion of the power deliver via 523, a portion of the signal via 521, and portions of I/O signal vias 513. In some embodiments, the I/O die 504 and I/O signal vias 523 can be the same as or similar to corresponding elements described above with reference to FIGS. 3A-B, and 4D.

The memory die 505 can include a portion of the power delivery via 523, a portion of the signal via 521, and portions of I/O signal vias 513. In some embodiments, the memory die 505 (e.g., the application die), can be the same as or similar to corresponding elements described above with reference to FIGS. 3A-B, and 4A-D.

FIG. 5B illustrates a side-view of substrate stack 500B, according to some aspects of the disclosure. The substrate stack 500B can include a lower layer 501, an upper layer 503, an I/O die 504, and one or more memory dies 505.

FIG. 5B differs from FIG. 5A, in that the lower layer 501 does not include a waveguide or turning element (e.g., waveguide 502, turning element 533 of FIG. 5A). Instead, the emitter 508 and detector 509 receive signals from the signal via 521 and are coupled with a fiber bundle 534. The fiber bundle 534 can be routed to another computing device or substrate stack.

FIG. 6 illustrates a side-view of a substrate stack 600, according to some aspects of the disclosure. The substrate stack 600 includes a backplane 621, a base die 604, and memory dies 605-1, 605-2, 605-3.

The chip power delivery vias 610 can extend through each of the backplane 621, base die 604, and memory dies 605-1, 605-2, 605-3. The chip power delivery vias 610 provide power to the base die 604 and memory dies 605-1, 605-2, 605-3.

The backplane power delivery vias 621 provide power to the backplane 620. In some embodiments, signal vias 613 can be disconnected from the backplane power delivery vias 621, but in the same or similar x-axis, y-axis location as the backplane power delivery vias 621 (e.g., shifted in the z-direction, where the x-axis runs horizontally along the bottom of the illustrated substrate stack 600, the y-axis runs perpendicularly into the page, and the z-axis runs vertically along the side of the illustrated substrate stack 600). In such embodiments, the signal vias 613 can carry data signals between the base die 604 and the memory dies 605-1, 605-2, 605-3.

The integrated optical component vias 630 can extend through each of the backplane 621, base die 604, and memory dies 605-1, 605-2, 605-3. The integrated optical component vias 630 can transfer data signals from the backplane 620 up to one or more of the base die 604, or memory dies 605-1, 605-2, 605-3. For example, the backplane 620 can receive an optical data signal via a detector, such as detector 509 of FIGS. 5A-B and convert the optical data signal to an electrical data signal. The electrical data signal can be transferred up to the base die 604 and one or more of the memory dies 605-1, 605-2, 605-3.

Each of the elements of the substrate stack 600 can be the same as or similar to corresponding elements described above with reference to FIGS. 3A-5B.

The preceding description sets forth numerous specific details such as examples of specific systems, components, methods, and so forth, in order to provide a good understanding of several embodiments of the present disclosure. It will be apparent to one skilled in the art, however, that at least some embodiments of the present disclosure may be practiced without these specific details. In other instances, well-known components or methods are not described in detail or are presented in simple block diagram format in order to avoid unnecessarily obscuring the present disclosure. Thus, the specific details set forth are merely exemplary. Particular implementations may vary from these exemplary details and still be contemplated to be within the scope of the present disclosure.

As used herein, the singular forms “a,” “an,” and “the” include plural references unless the context clearly indicates otherwise. Thus, for example, reference to “a precursor” includes a single precursor as well as a mixture of two or more precursors; and reference to a “reactant” includes a single reactant as well as a mixture of two or more reactants, and the like.

Reference throughout this specification to “one embodiment” or “an embodiment” means that a particular feature, structure, or characteristic described in connection with the embodiment is included in at least one embodiment. Thus, the appearances of the phrase “in one embodiment” or “in an embodiment” in various places throughout this specification are not necessarily all referring to the same embodiment. In addition, the term “or” is intended to mean an inclusive “or” rather than an exclusive “or.” When the term “about” or “approximately” is used herein, this is intended to mean that the nominal value presented is precise within ±10%, such that “about 10” would include from 9 to 11.

The term “at least about” in connection with a measured quantity refers to the normal variations in the measured quantity, as expected by one of ordinary skill in the art in making the measurement and exercising a level of care commensurate with the objective of measurement and precisions of the measuring equipment and any quantities higher than that. In certain embodiments, the term “at least about” includes the recited number minus 10% and any quantity that is higher such that “at least about 10” would include 9 and anything greater than 9. This term can also be expressed as “about 10 or more.” Similarly, the term “less than about” typically includes the recited number plus 10% and any quantity that is lower such that “less than about 10” would include 11 and anything less than 11. This term can also be expressed as “about 10 or less.”

Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to illuminate certain materials and methods and does not pose a limitation on scope. No language in the specification should be construed as indicating any non-claimed element as essential to the practice of the disclosed materials and methods.

Although the operations of the methods herein are shown and described in a particular order, the order of the operations of each method may be altered so that certain operations may be performed in an inverse order or so that certain operation may be performed, at least in part, concurrently with other operations. In another embodiment, instructions or sub-operations of distinct operations may be in an intermittent and/or alternating manner.

It is to be understood that the above description is intended to be illustrative, and not restrictive. Many other embodiments will be apparent to those of skill in the art upon reading and understanding the above description. The scope of the disclosure should, therefore, be determined with reference to the appended claims, along with the full scope of equivalents to which such claims are entitled.

What is claimed is:

1. A device comprising:
a first signal pad comprising:
a first electrically conductive layer, and
a first complementary metal-oxide-semiconductor (CMOS) layer coupled to the first electrically conductive layer, the first CMOS layer comprising a first light source driver coupled to a first light source, and a first photodetector coupled to a first transimpedance amplifier;
a second signal pad comprising;
a second electrically conductive layer, and
a second CMOS layer coupled to the second electrically conductive layer, the second CMOS layer comprising a second light source driver coupled to a second light source, and a second photodetector coupled to a second transimpedance amplifier; and
an optical medium that connects the first signal pad with the second signal pad, wherein the optical medium is configured to couple a first optical signal from the first light source with the second photodetector, and wherein the optical medium is configured to couple a second optical signal from the second light source with the first photodetector.

2. The device of claim 1, wherein the optical medium comprises a plurality of optical fibers.

3. The device of claim 1, wherein the optical medium comprises a plurality of waveguides.

4. The device of claim 3, wherein wherein a portion of the first signal pad is embedded in a cladding layer on a substrate, a portion of the second signal pad is embedded in the cladding layer on the substrate, and the waveguide is embedded in the cladding layer on the substrate.

5. The device of claim 1, wherein the first CMOS layer further comprises a plurality of power delivery pads, wherein the first CMOS layer is powered via the plurality of power delivery pads.

6. The device of claim 5, wherein a first side of the CMOS layer comprises the plurality of power delivery pads, and wherein a second side of the CMOS layer comprises the first electrically conductive layer.

7. The device of claim 1, wherein the first signal pad is electrically connected to a semiconductor device.

8. The device of claim 7, wherein the first CMOS layer further comprises a plurality of through-silicon vias (TSVs), wherein the plurality of TSVs are configured to provide power to the semiconductor device electrically connected to the first signal pad.

9. The device of claim 8, wherein the semiconductor device is a memory device.

10. The device of claim 1, wherein the first light source comprises a micro-light emitting diode (LED).

11. The device of claim 1, wherein the first light source comprises a vertical-cavity surface-emitting laser (VCSEL).

12. The device of claim 1, further comprising:
a first turning element configured to redirect an optical signal between the optical medium and the first signal pad; and
a second turning element configured to redirect the optical signal between the optical medium and the second signal pad.

13. The device of claim 1, wherein the first CMOS layer further comprises a plurality of micro bumps configured to mechanically bond to a substrate.

14. The device of claim 1, wherein the CMOS layer further comprises a plurality of power delivery pads, wherein the first CMOS layer is powered via the plurality of power delivery pads, and
wherein the CMOS layer further comprises a plurality of through-silicon vias (TSVs), wherein the plurality of TSVs are configured to provide power to a semiconductor device electrically connected to the first signal pad.

15. A device, comprising:
a substrate comprising an optical medium and a plurality of vias;
a signal pad formed on the substrate, the signal pad comprising a complementary metal-oxide-semiconductor (CMOS) backplane that comprises a light source driver coupled to a light source and a photodetector coupled to a transimpedance amplifier; and
a semiconductor component disposed on the signal pad;
wherein a first subset of the plurality of vias are through vias that power the semiconductor component and wherein a second subset of the plurality of vias power the CMOS layer.

16. The device of claim 15, wherein power to the CMOS layer maintains the CMOS layer at a bias voltage, and wherein a millivolt-range signal, when added to the bias voltage, causes activation of the light source.

17. The device of claim 16, further comprising an amplifier connected to the light source, wherein the millivolt-range signal is amplified by the amplifier.

18. The device of claim 15, wherein the light sources comprises one of a micro-light emitting diode (LED), or a vertical-cavity surface-emitting laser (VCSEL).

19. The device of claim 15, wherein the optical medium comprises one of one or more optical fibers or one or more waveguides.

20. A system comprising:
a first semiconductor device;
a second semiconductor device; and
an embedded photonic interconnect that couples the first semiconductor device to the second semiconductor device, wherein the embedded photonic interconnect comprises:
a first signal pad coupled to the first semiconductor device, the first signal pad comprising:
a first electrically conductive layer, and
a first complementary metal-oxide-semiconductor (CMOS) layer coupled to the first electrically conductive layer, the first CMOS layer comprising a first light source driver coupled to a first light source, and a first photodetector coupled to a first transimpedance amplifier;
a second signal pad coupled to the second semiconductor device, the second signal pad comprising;
a second electrically conductive layer, and
a second CMOS layer coupled to the second electrically conductive layer, the second CMOS layer comprising a second light source driver coupled to a second light source, and a second photodetector coupled to a second transimpedance amplifier; and
an optical medium that connects the first signal pad with the second signal pad, wherein the optical medium is configured to couple a first optical signal from the first light source with the second photodetector, and wherein the optical medium is configured to couple a second optical signal from the second light source with the first photodetector.
